(19) United States
(12) Patent Application Publication
(10) Pub. No.: US 2025/0287185 A1
(43) Pub. Date: Sep. 11, 2025

(54) METHOD, APPARATUS AND PROGRAM FOR TRACKING LOCATION BASED ON DATA LOGGERS THAT OPTIMIZE BATTERY LIFE

(71) Applicant: INDUSTRY-UNIVERSITY COOPERATION FOUNDATION HANYANG UNIVERSITY ERICA CAMPUS, Ansan-si (KR)

(72) Inventors: Song Jun LEE, Seoul (KR); Hyuk JI, Hwaseong-si (KR); Seong Hwan SON, Ansan-si (KR)

(73) Assignee: INDUSTRY-UNIVERSITY COOPERATION FOUNDATION HANYANG UNIVERSITY ERICA CAMPUS, Ansan-si (KR)

(21) Appl. No.: 19/199,669

(22) Filed: May 6, 2025

Related U.S. Application Data
(63) Continuation of application No. PCT/KR2025/002928, filed on Mar. 5, 2025.

(30) Foreign Application Priority Data
Mar. 6, 2024 (KR) 10-2024-0031938

(51) Int. Cl. H04W 4/029; G01R 31/367; G06F 11/34

(52) U.S. Cl. CPC H04W 4/029; G01R 31/367; G06F 11/3476

(57) ABSTRACT

A method of tracking a location based on data loggers that optimize battery life according to various embodiments of the present invention is disclosed. The method may include: recognizing a plurality of storage devices in which goods having the same destination are stored; determining at least one of a plurality of data loggers provided in the plurality of storage devices to be a master logger; receiving data related to the storage device provided with the master logger from the master logger; and tracking locations of the plurality of storage devices based on the data.

### CROSS-REFERENCE TO RELATED APPLICATIONS

This application is a Continuation of International Application No. PCT/KR2025/002928, filed Mar. 5, 2025, which claims the benefit of Korean Patent Application No. 10-2024-0031938, filed on Mar. 6, 2024, in the Korean Intellectual Property Office, the disclosure of which is incorporated herein in its entirety by reference.

### TECHNICAL FIELD

The present invention relates to a method, apparatus, and program for location tracking based on data loggers that optimize battery life, and more particularly, to a method, apparatus and program for tracking a location while optimizing battery life of a data logger by dynamically selecting a data logger that provides location information in a location tracking system.

### BACKGROUND ART

Location tracking technology is developing rapidly, and its application range is extensive from logistics management to personal security and vehicle monitoring. Modern location tracking systems utilize a plurality of data loggers to collect real-time location data and designate one of the data loggers as a main master data logger (hereinafter referred to as a master logger) to transmit information to a central server or an end user.

However, the structure has significant limitations in terms of battery life, durability of a device, and environmental adaptability, as the selection of the master logger is fixed by initial settings. In particular, when the battery of the fixed master logger is depleted or malfunctions, the reliability and efficiency of the entire system may be significantly reduced. In addition, the existing fixed master logger approach limits potential capacity of the location tracking system.

The location tracking system may be seriously limited, especially in fields requiring remote location tracking, long-term data collection, and reliable monitoring under various environmental conditions.

Meanwhile, markets are demanding innovative location tracking solutions with energy efficiency, long-term reliability, and flexible system management capabilities. These requirements are becoming increasingly important, especially in advanced technology fields such as smart cities, autonomous vehicles, and remote asset management.

Therefore, it is necessary to develop a location tracking technology that overcomes these limitations of the existing system and meets the market demand. In this regard, Korean Registered Patent No. 10-2613524 discloses a method and system for optimizing refrigerated logistics that improve adaptability to logistics volume fluctuations based on real-time vehicle movement tracking.

### DISCLOSURE

### Technical Problem

The present invention is directed to providing a method, apparatus, and program of tracking a location based on data loggers that optimize battery life.

However, aspects of the present invention are not restricted to those set forth herein. The above and other aspects of the present invention will become more apparent to one of ordinary skill in the art to which the present invention pertains by referencing the detailed description of the present invention given below.

### Technical Solution

According to an aspect of the present invention, there is provided a method of tracking a location based on data loggers that optimize battery life is disclosed. The method includes: recognizing a plurality of storage devices in which goods having the same destination are stored; determining at least one of a plurality of data loggers provided in the plurality of storage devices to be a master logger; receiving data related to the storage device provided with the master logger from the master logger; and tracking locations of the plurality of storage devices based on the data.

The determining of the at least one of the plurality of data loggers provided in the plurality of storage devices to be the master logger may include: recognizing states of charge of each of the plurality of data loggers; and determining a specific data logger corresponding to a highest state of charge among the states of charge of each of the plurality of data loggers to be the master logger.

The method may further include: after the master logger is determined, monitoring whether the master logger is in a communication failure state; and when it is recognized that the master logger is in the communication failure state, activating an alternative communication protocol.

The communication failure state may include a radio blocking state or a weak electric field state, and the monitoring of whether the master logger is in the communication failure state may include: monitoring whether the communication failure state is the radio blocking state based on whether data is received from the master logger at each preset cycle; or monitoring whether the weak electric field state occurs based on whether a difference between a first time corresponding to the preset cycle and a second time at which the data is received from the master logger exceeds a preset time.

The activating of the alternative communication protocol may include: determining some of the plurality of data loggers to be the master logger; receiving multiple pieces of data from each of the plurality of master loggers; and tracking locations of the plurality of storage devices based on the multiple pieces of data.

The tracking of the locations of the plurality of storage devices based on the multiple pieces of data may include: recognizing a plurality of latitude values and a plurality of longitude values included in the multiple pieces of data; recognizing a specific latitude value having a largest mutual overlap frequency among the plurality of latitude values and recognizing a specific longitude value having a largest mutual overlap frequency among the plurality of longitude values; and tracking the locations of the plurality of storage devices based on the specific latitude value and the specific longitude value.

The method may further include: monitoring whether the communication of the master logger is restored after the activating of the alternative communication protocol; deactivating the alternative communication protocol when it is recognized that the communication of the master logger is restored; recognizing the states of charge of each of the plurality of data loggers in connection with the deactivating of the alternative communication protocol; and re-determining a specific data logger corresponding to a highest state of charge among the states of charge of each of the plurality of data loggers to be the master logger.

The monitoring of whether the communication of the master logger is restored may include: transmitting a response request signal to the master logger in the communication failure state at each preset time; and monitoring whether the communication of the master logger is restored based on a response signal corresponding to the response request signal, in which, when the response signal corresponding to the response request signal is not received from the master logger, it may be recognized that the communication of the master logger in the communication failure state is not restored, and when the response signal is received from the master logger and a time at which the response signal is received is included within a preset time from the time at which the response request signal is transmitted, it may be recognized that the communication of the master logger in the communication failure state is restored.

According to another aspect of the present invention, there is provided an apparatus. The apparatus includes: a memory configured to store one or more instructions; and a processor configured to execute the one or more instructions stored in the memory, in which the processor may perform the above-described methods by executing the one or more instructions.

According to still another aspect of the present invention, there is provided a computer program coupled to a computer, which is hardware, and stored in a computer-readable recording medium to execute the above-described methods.

Other detailed content of the present invention is described in the detailed description and illustrated in the drawings.

### Advantageous Effects

According to the present invention, it is possible to minimize the battery consumption of the data logger while maintaining the optimized location tracking for the network related to the location tracking. In addition, according to the present invention, by activating the alternative communication protocol when the communication failure occurs, it is possible to maintain the continuity of the network related to the location tracking, optimize the battery life of the data logger, and improve the accuracy of the location tracking.

Therefore, according to the present invention, it is possible to greatly improve the reliability and data transmission efficiency of the location tracking system. In addition, according to the present invention, it is possible to provide a longer life, higher data reliability, and greater system flexibility through intelligent energy management between the devices.

Effects of the present invention are not limited to the effects described above, and other effects that are not mentioned may be obviously understood by those skilled in the art from the following description.

### DESCRIPTION OF DRAWINGS

The above and other objects, features and advantages of the present invention will become more apparent to those of ordinary skill in the art by describing exemplary embodiments thereof in detail with reference to the accompanying drawings, in which:

FIG. 1 is a diagram illustrating a system according to an embodiment of the present invention;

FIG. 2 is a hardware configuration diagram of a computing device according to an embodiment of the present invention; and

FIGS. 3 to 7 are diagrams for describing an example of a method of tracking a location based on data loggers that optimize battery life according to an embodiment of the present invention.

### MODES OF THE INVENTION

Hereinafter, various embodiments will be described with reference to the drawings. In this specification, various descriptions are presented to provide an understanding of the invention. However, it is obvious that these embodiments may be practiced without these specific descriptions.

The terms “component,” “module,” “system,” etc., used herein refer to a computer-related entity, hardware, firmware, software, a combination of software and hardware, or an implementation of software. For example, a component may be, but is not limited to, a procedure running on a processor, a processor, an object, an execution thread, a program, and/or a computer. For example, both an application running on a computing device and the computing device may be a component. One or more components may reside within a processor and/or execution thread. One component may be localized within one computer. One component may be distributed between two or more computers. In addition, these components may be executed from various computer-readable media having various data structures stored therein. Components may communicate via local and/or remote processes (e.g., data from one component interacting with other components through signals in a local system and a distributed system and/or data transmitted to other systems via networks such as the Internet), for example according to signals with one or more data packets.

In addition, the term “or” is intended to mean an inclusive “or,” not an exclusive “or.” That is, unless otherwise specified or clear from context, “X uses A or B” is intended to mean one of the natural implicit substitutions. That is, “X uses A or B” may apply to any of the cases in which X uses A; X uses B; or X uses both A and B. In addition, the term “and/or” used herein should be understood to refer to and include all possible combinations of one or more of the related goods listed.

In addition, the terms “include” and/or “including” should be understood to mean that the corresponding feature and/or component is present. However, the terms “include” and/or “including” should be understood as not excluding the presence or addition of one or more other features, components and/or groups thereof. In addition, unless otherwise specified or the context clearly indicates a singular form, the singular form in the present specification and in the claims should generally be construed to mean “one or more.”

In addition, those skilled in the art should recognize that various illustrative logical blocks, configurations, modules, circuits, means, logic, algorithms, and steps described in connection with the embodiments disclosed herein may be implemented by electronic hardware, computer software, or a combination of both. To clearly illustrate interchangeability of hardware and software, various illustrative components, blocks, configurations, means, logics, modules, circuits, and steps have been described above generally in terms of their functionality. Whether such functionality is implemented by hardware or software will depend on the specific application and design constraints imposed on the overall system. Those skilled in the art may implement the described functionality in a variety of ways for each specific application. However, such implementation determinations should not be construed as departing from the scope of the present invention.

The description of the presented embodiments is provided to enable those skilled in the art to make or use the present invention. Various modifications to these embodiments will be apparent to those skilled in the art. The general principles defined herein may be applied to other embodiments without departing from the scope of the invention. Therefore, the present invention is not limited to the embodiments presented herein. The present invention should be interpreted in the broadest scope consistent with the principles and novel features presented herein.

In this specification, a computer is any kind of hardware device including at least one processor and can be understood as including a software configuration which is operated in the corresponding hardware device according to the embodiment. For example, the meaning of “computer” may be understood to include all of smart phones, tablet PCs, desktops, laptops, and user clients and applications running on each device, but is not limited thereto.

Hereinafter, embodiments of the present invention will be described in detail with reference to the accompanying drawings.

Each step described in this specification is described as being performed by the computer, but subjects of each step are not limited thereto, and according to embodiments, at least some of each step can also be performed on different devices.

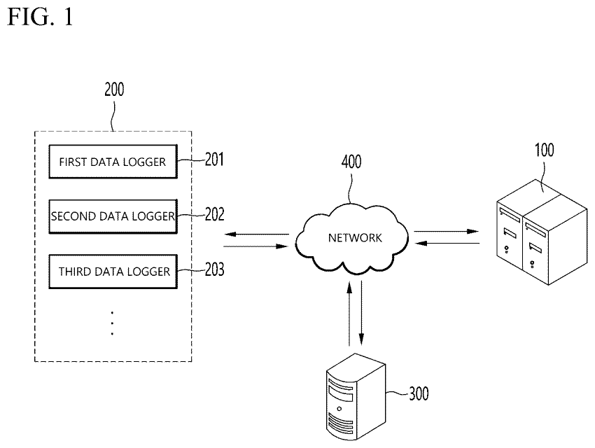

FIG. 1 is a diagram illustrating a system according to an embodiment of the present invention.

Referring to FIG. 1, the system according to an embodiment of the present invention may include a computing device 100, a data logger 200, and an external server 300. Here, the system illustrated in FIG. 1 is according to an embodiment, and components of the system are not limited to the embodiment illustrated in FIG. 1, and may be added, changed, or omitted as necessary.

In an embodiment, the computing device 100 may perform a method of tracking a location based on data loggers that optimize battery life. For example, the computing device 100 may track a location of an item by utilizing a data logger that optimizes battery life in a logistics system.

Specifically, the computing device 100 may recognize a plurality of storage devices in which goods having the same destination are stored. In addition, the computing device 100 may determine (or select) at least one of the plurality of data loggers 200 provided in the plurality of storage devices to be a master logger. Here, the master logger may be a specific data logger with the highest state of charge among the plurality of data loggers 200 but is not limited thereto.

In addition, the computing device 100 may receive data related to a storage device provided with the master logger from the master logger. The computing device 100 may track the locations of the plurality of storage devices based on the data.

Accordingly, the computing device 100 of the present invention may minimize the battery consumption of the data logger while maintaining the optimized location tracking for the network related to the location tracking.

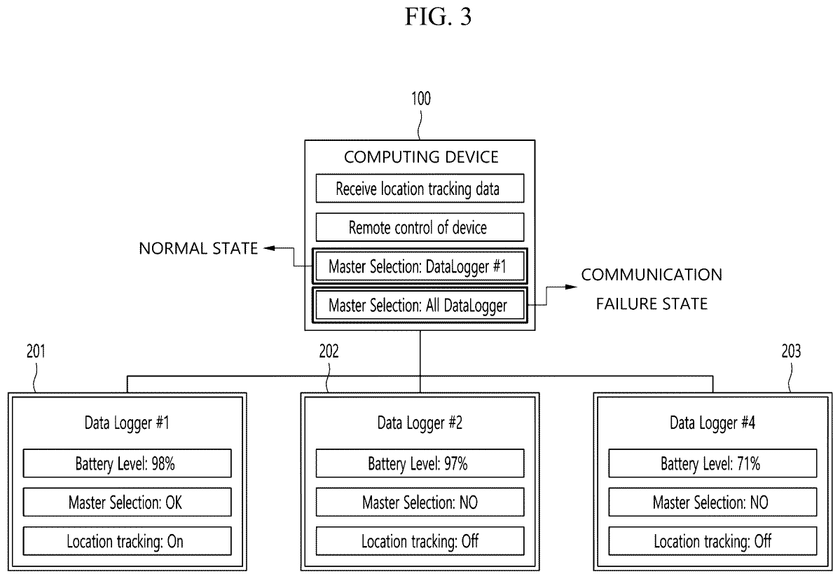

Hereinafter, an example of a method in which the computing device 100 performs a method of tracking a location based on data loggers that optimize battery life will be described with reference to FIGS. 3 to 7.

In various embodiments, the computing device 100 may provide a web-based service or an application-based service. However, the present invention is not limited thereto.

The computing device 100 may include any type of computer system or computer device, such as a microprocessor, a mainframe computer, a digital processor, a portable device, and a device controller. However, the present invention is not limited thereto.

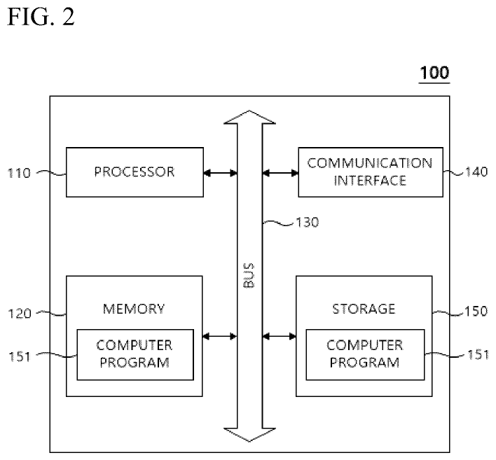

Hereinafter, a hardware configuration of the computing device 100 will be described with reference to FIG. 2.

In an embodiment, the data logger 200 may be provided in a storage device for storing transported goods/cargo. Here, the storage device may be a box-shaped device for storing goods/cargo, etc. In addition, the storage device may include the data logger 200, a storage unit, a sensor unit, a communication unit, a display unit, etc., and may be connected to the computing device 100 via a network. In addition, the storage device may transmit and receive various types of information/data necessary to provide a transport cargo management service to and from the computing device 100.

The data logger 200 may be connected to the computing device 100 via the storage device. However, the present invention is not limited thereto, and the data logger 200 may be directly connected to the computing device 100 by including a separate network module.

Specifically, the data logger 200 may be connected to the computing device 100 via the network 400 and may be an electronic device that provides location information used in a location tracking method performed by the computing device 100.

Here, the data logger 200 may include various types of electronic devices. Specifically, the data logger 200 may automatically monitor various parameters of the environment, record the monitored parameters over time, record geographical location information using location recognition technology, and transmit the geographical location information to the computing device 100.

For example, the data logger 200 may accurately measure location information such as latitude, longitude, and altitude by regularly receiving satellite signals through a built-in location recognition sensor. Here, the location recognition sensor may include various sensors based on technologies such as GPS, LTE Cell Locate, Bluetooth, ZigBee, and WiFi.

In addition, the data logger 200 may record each location data point with a time stamp and provide an accurate record of where an object (e.g., a storage device for goods) provided with the data logger 200 is at a specific time. In addition, the data logger 200 may store location data in an internal memory, and the stored data may be transmitted to the computing device 100.

In addition, the data logger 200 may measure physical or electrical conditions such as temperature, humidity, pressure, pH, electrical conductivity, vibration, speed, sound, light intensity, current, and voltage, through various sensors. In this case, the data logger 200 may store the measured data and transmit the data to the computing device 100 for analysis of the stored data.

In addition, the data logger 200 may include a communication function based on a cellular network, satellite communication, or Wi-Fi connection for transmitting data to the computing device 100.

Such a data logger 200 can be driven by a battery, and when the battery is used efficiently, the usage time of the data logger 200 may increase, thereby improving the efficiency of the location tracking system.

The external server 300 may be connected to the computing device 100 through the network 400, the computing device 100 may transmit and receive various types of information/data necessary for performing the method of tracking a location based on data loggers that optimize battery life, and the computing device 100 may store and manage various types of information/data generated by performing the method of tracking a location based on data loggers that optimize battery life.

For example, the external server 300 may be a database server that stores the information used in the method of tracking a location based on data loggers that optimize battery life. As another example, the external server 300 may be a server that provides the information used in the location tracking method based on the data logger that optimizes the battery life.

The network 400 may be a connection structure that enables information exchange between nodes, such as a computing device, a plurality of terminals, and servers. For example, the network 400 may include a local area network (LAN), a wide area network (WAN), the Internet (World Wide Web (WWW)), a wired/wireless data communication network, a telephone network, a wired/wireless television communication network, or the like.

The wireless data communication network may include 3G, 4G, 5G, 3rd Generation Partnership Project (3GPP), 5th Generation Partnership Project (5GPP), Long Term Evolution (LTE), World Interoperability for Microwave Access (WiMAX), Wi-Fi, the Internet, a LAN, a wireless LAN (WLAN), a WAN, a personal area network (PAN), radio frequency, a Bluetooth network, a near-field communication (NFC) network, a satellite broadcast network, an analog broadcast network, a digital multimedia broadcasting (DMB) network, and the like, but is not limited thereto.

FIG. 2 is a hardware configuration diagram of a computing device according to an embodiment of the present invention.

Referring to FIG. 2, the computing device 100 according to an embodiment of the present invention may include one or more processors 110, a memory 120 that loads a computer program 151 executed by the processor 110, a bus 130, a communication interface 140, and a storage 150 that stores the computer program 151. Here, only the components related to the embodiment of the present invention are illustrated in FIG. 2. Accordingly, those skilled in the art to which the present invention pertains may understand that general-purpose components other than those illustrated in FIG. 2 may be further included.

The processor 110 controls an overall operation of each component of the computing device 100. The processor 110 may be composed of one or more cores and may include a processor for data analysis and deep learning, such as a central processing unit (CPU), a general purpose graphics processing unit (GPGPU), a tensor processing unit (TPU), etc., of a computing device. Alternatively, the processor may be configured to include any form of processor well known in the art of the present invention.

In addition, the processor 110 may perform an operation on at least one application or program for executing the method according to the embodiments of the present invention, and the computing device 100 may include one or more processors.

In various embodiments, the processor 110 may further include a random access memory (RAM) (not illustrated) and a read-only memory (ROM) for temporarily and/or permanently storing signals (or data) processed in the processor 110. In addition, the processor 110 may be implemented in the form of a system-on-chip (SoC) including at least one of a graphics processing unit, a RAM, and a ROM.

The memory 120 stores various data, commands, and/or information. The memory 120 may load the computer program 151 from the storage 150 to execute methods/operations according to various embodiments of the present invention. When the computer program 151 is loaded into the memory 120, the processor 110 may perform the method/operation by executing one or more instructions constituting the computer program 151. The memory 120 may be implemented as a volatile memory such as a RAM, but the technical scope of the present invention is not limited thereto.

The bus 130 provides a communication function between the components of the computing device 100. The bus 130 may be implemented as various types of buses, such as an address bus, a data bus, and a control bus.

The communication interface 140 supports wired/wireless Internet communication of the computing device 100. In addition, the communication interface 140 may support various communication manners other than the Internet communication. To this end, the communication interface 140 may be configured to include a communication module well known in the art of the present invention. In some embodiments, the communication interface 140 may be omitted.

The storage 150 may non-temporarily store the computer program 151. When performing the process according to an embodiment of the present invention through the computing device 100, the storage 150 may store various types of information necessary to perform a method according to the disclosed embodiment or to provide a service.

The storage 150 may include a nonvolatile memory, such as a ROM, an erasable programmable ROM (EPROM), an electrically erasable programmable ROM (EEPROM), and a flash memory, a hard disk, a removable disk, or any well-known computer-readable recording medium in the art to which the present invention pertains.

The computer program 151 may include one or more instructions to cause the processor 110 to perform methods/operations according to various embodiments of the present invention when loaded into the memory 120. That is, the processor 110 may perform the method/operation according to various embodiments of the present invention by executing the one or more instructions.

In an embodiment, the computer program 151 may include one or more instructions for performing various methods associated with various tasks related to training a neural network model.

Operations of the method or algorithm described with reference to the embodiment of the present invention may be directly implemented in hardware, in software modules executed by hardware, or in a combination thereof. The software module may reside in a RAM, a ROM, an EPROM, an EEPROM, a flash memory, a hard disk, a removable disk, a CD-ROM, or in any form of computer-readable recording media known in the art to which the invention pertains.

The components of the present invention may be embodied as a program (or application) and stored in media for execution in combination with a computer which is hardware. The components of the present invention may be executed in software programming or software elements, and similarly, embodiments may be realized in a programming or scripting language such as C, C++, Java, or an assembler, including various algorithms implemented in a combination of data structures, processes, routines, or other programming constructions. Functional aspects may be implemented in algorithms executed on one or more processors.

FIGS. 3 to 7 are diagrams for describing an example of a method of tracking a location based on data loggers that optimize battery life according to an embodiment of the present invention.

FIG. 3 is a diagram schematically illustrating an embodiment of the method of tracking a location based on data loggers that optimize battery life according to the present invention.

Referring to FIG. 3, it is described on the assumption that there are a first data logger 201, a second data logger 202, and a third data logger 203 and that a state of charge of the first data logger 201 is 98%, a state of charge of the second data logger 202 is 97%, and a state of charge of the third data logger 203 is 71%.

When the communication is in the normal state, the computing device 100 may determine (or select) the first data logger 201, which has the highest state of charge among the first data logger 201, the second data logger 202, and the third data logger 203, as the master logger. Here, the first data logger 201 determined as the master logger may collect data for location tracking and transmit the collected data to the computing device 100. In addition, the second data logger 202 and the third data logger 203, which are not the master loggers, may not collect the data for location tracking or transmit anything to the computing device 100.

Therefore, when the communication is in the normal state, the computing device 100 may control only the first data logger 201 having the highest state of charge to be activated, thereby saving the batteries of the second data logger 202 and the third data logger 203.

Meanwhile, when the communication is in the failure state, the computing device 100 may determine the first data logger 201, the second data logger 202, and the third data logger 203 as the master logger. In this case, the first data logger 201, the second data logger 202, and the third data logger 203 may each collect the data for location tracking and transmit the collected data to the computing device 100.

Therefore, the computing device 100 may maintain the continuity of the network related to the location tracking when there is a communication failure.

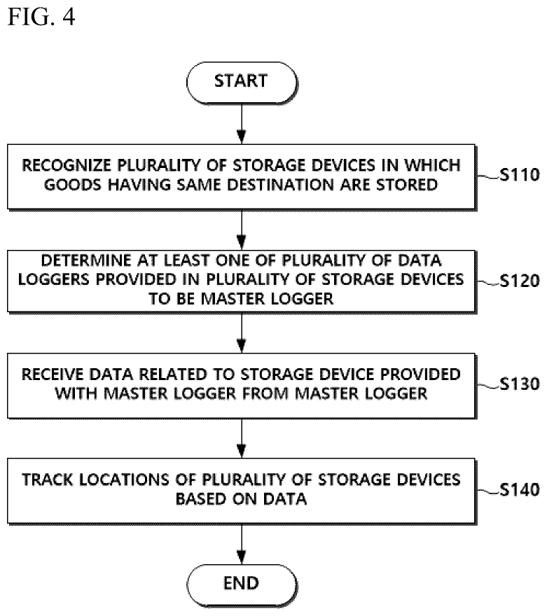

Hereinafter, referring to FIGS. 4 to 7, a specific embodiment of the method of tracking a location based on data loggers that optimize battery life according to the present invention will be described.

Referring to FIG. 4, the computing device 100 may recognize the plurality of storage devices in which goods having the same destination are stored (S110).

For example, the computing device 100 may group goods scheduled to move to the same destination by utilizing a unique identification code assigned to each storage device and an identification code of goods stored inside the storage device. In this way, the computing device 100 may perform efficient logistics management and delivery optimization by combining the location where the goods are stored and final destination information of each storage device.

For example, the computing device 100 may classify a storage device including all goods to be delivered to city A into a group and adjust the storage devices belonging to the group to follow the same logistics route.

In addition, the computing device 100 may recognize the data logger 200 provided in each of the storage devices belonging to the corresponding group and determine at least one master logger based on the recognized data logger 200.

The computing device 100 may determine at least one of the plurality of data loggers 200 provided in the plurality of storage devices classified into one group as the master logger (S120).

Specifically, when the computing device 100 determines at least one of the plurality of data loggers 200 provided in the plurality of storage devices to be the master logger, the computing device 100 may recognize the states of charge of each of the plurality of data loggers 200. The computing device 100 may determine the specific data logger 200 corresponding to the highest state of charge among the states of charge of each of the plurality of data loggers 200 as the master logger.

In various embodiments, the computing device 100 may perform a step (S120) of determining at least one of the plurality of data loggers to be the master logger at each preset time.

For example, the computing device 100 may re-select the master logger daily, weekly, or at other periodic intervals set by the user. In this process, the computing device 100 may consider the communication range, signal strength, connection reliability, data transmission speed, and other performance-related parameters of each data logger 200. The computing device 100 may comprehensively analyze these parameters to determine the master logger that may most efficiently manage the network and optimize the data transmission. For example, when the computing device 100 re-selects the master logger by considering the batteries of the plurality of data loggers 200, the state of charge of the plurality of data loggers 200 may be controlled to decrease while maintaining a similar state, thereby increasing the overall usage time of the plurality of data loggers 200.

As another example, the computing device 100 may select the master logger by considering the location information of the data loggers 200 and the distance to the destination. For example, by selecting the data logger closest to the destination or located on the path as the master logger, faster data transmission and accurate location tracking are possible. In this way, the dynamic selection of the master logger may improve the energy efficiency of the entire network and improve the efficiency of logistics management, thereby ultimately extending the battery life.

The computing device 100 may receive the data related to the storage device provided with the master logger from the master logger (S130). Then, the computing device 100 may track the locations of the plurality of storage devices based on the received data (S140).

In an embodiment, the data transmitted from the master logger to the computing device 100 may include location information (e.g., latitude and longitude) corresponding to the current location of the storage device. In addition, the data may include a movement speed, a movement direction, a history of movement path, and environmental conditions (e.g., temperature and humidity) of the storage device, the open/closed state of the storage device, the battery level, a relative distance to other storage devices in the vicinity, and the location information.

The data may be analyzed by the computing device 100 to determine the exact real-time location and state of each storage device, and may provide a basis for taking additional actions, such as adjusting the path, calculating the expected arrival time, and monitoring the security and safety, if necessary. In other words, the data transmitted from the master logger to the computing device 100 may include information that may contribute to optimizing the logistics management system, reducing costs, and improving customer service.

The computing device 100 may use the data to quickly detect unexpected delays or failures and support appropriate responses. For example, when the storage device deviates from the scheduled path or is delayed in its expected arrival time, the computing device 100 may recognize the situation and take related actions, such as tracking goods, managing inventory, and transmitting notifications to customers.

According to various embodiments of the present invention, the computing device 100 may activate the alternative communication protocol when the predetermined master logger is in the communication failure state. Here, the communication failure state may include, but is not limited to, the radio blocking state or the weak electric field state.

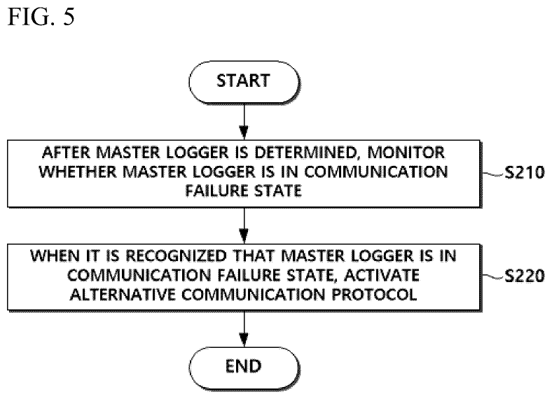

Specifically, referring to FIG. 5, the computing device 100 may monitor whether the master logger is in the communication failure state after the master logger is determined (S210).

When the computing device 100 monitors whether the master logger is in the communication failure state, the computing device 100 may monitor whether the communication failure state is the radio blocking state based on whether data that should be received from the master logger at each preset cycle is received.

For example, the computing device 100 may recognize that the communication failure state is the radio blocking state when no data is received from the master logger during the preset cycle. Meanwhile, the computing device 100 may recognize that the communication failure state is not the radio blocking state when data is received within an expected time.

In addition, the computing device 100 may monitor whether the communication failure state is the weak electric field state based on whether a difference between a first time corresponding to the preset cycle and a second time at which data is received from the master logger exceeds the preset time.

For example, the computing device 100 may recognize that the communication failure state is the weak electric field state when the data reception from the master logger is continuously delayed or occurs irregularly. Conversely, the computing device 100 may recognize that the communication failure state is not the weak electric field state when the data reception from the master logger is stably performed at a regular period and the amount or quality of the received data satisfies a certain standard.

By the monitoring method, the computing device 100 may quickly evaluate the communication state of the master logger and take appropriate measures if necessary, thereby maintaining the stability and efficiency of the entire system.

When the computing device 100 recognizes that the master logger is in the communication failure state, the computing device 100 may activate the alternative communication protocol (S220).

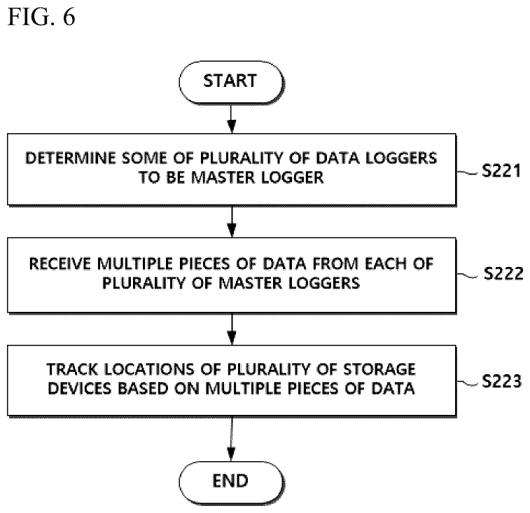

Specifically, referring to FIG. 6, when the computing device 100 activates the alternative communication protocol, the computing device 100 may determine some of the plurality of data loggers 200 as the master logger (S221).

For example, when the normal communication from the master logger is impossible, the computing device 100 may immediately activate the alternative communication protocol such as low-power Bluetooth, Wi-Fi Direct, or a cellular network. In this way, the computing device 100 may reconfigure connections with other data loggers 200 within the network and designate one or more of the data loggers as a new master logger.

For example, the computing device 100 may select a new master logger by evaluating the battery level, the signal strength, and the current location information of each data logger 200.

The computing device 100 may receive multiple pieces of data from each of the plurality of newly determined master loggers (S222). Then, the computing device 100 may track the locations of the plurality of storage devices based on the multiple pieces of data (S223).

For example, the computing device 100 receives location data from the newly selected master loggers, and the data may include latitude and longitude values of each storage device. Then, the computing device 100 may analyze overlapping values among the plurality of received latitude and longitude values to identify a specific location that is reported most frequently.

For example, when the computing device 100 tracks the locations of the plurality of storage devices based on the multiple data, the computing device 100 may recognize the plurality of latitude values and the plurality of longitude values included in multiple data. In addition, the computing device 100 may recognize a specific latitude value having the largest mutual overlap frequency among the plurality of latitude values and recognize a specific longitude value having the largest mutual overlap frequency among the plurality of longitude values. The computing device 100 may track the locations of the plurality of storage devices based on the specific latitude value and the specific longitude value.

For example, when more than half of the data loggers transmit data with latitude 35.6895 and longitude 139.6917, the computing device 100 may recognize the corresponding coordinates as the current location of the corresponding storage devices.

Therefore, the computing device 100 may effectively track the locations of the storage devices and maintain the accuracy of the data and the stability of the network even in the communication failure situation. This provides an important advantage especially in large-scale logistics and delivery networks and may ensure high reliability in tracking and managing the location of the storage device.

According to various embodiments of the present invention, the computing device 100 may monitor the communication status after activating the alternative communication protocol. The computing device 100 may deactivate the alternative communication protocol according to the monitoring result.

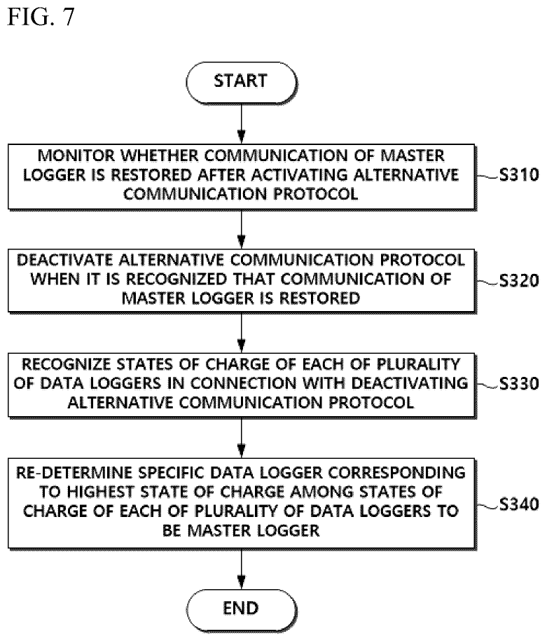

Specifically, referring to FIG. 7, the computing device 100 may monitor whether the communication of the master logger is restored after activating the alternative communication protocol (S310).

For example, when the computing device 100 monitors whether the communication of the master logger is restored, the computing device 100 may transmit a response request signal to the master logger in the communication failure state at each preset time. In addition, the computing device 100 may monitor whether the communication of the master logger is restored based on a response signal corresponding to the response request signal.

Here, when the response signal corresponding to the response request signal is not received from the master logger, the computing device 100 may recognize that the communication of the master logger, which was in the communication failure state, has not been restored.

For example, the computing device 100 may periodically transmit the response request signal to the master logger through the activated alternative communication protocol when the master logger is in the communication failure state. This request is to confirm the network connection status and communication function of the master logger. When the computing device 100 does not receive the response signal from the master logger within a set time, the computing device 100 may determine that the communication of the master logger is still not restored.

Meanwhile, the computing device 100 may recognize that the communication of the master logger, which is in the communication failure state, has been restored when the response signal is received from the master logger and the time at which the response signal is received is included within the preset time from the time at which the response request signal is transmitted.

Specifically, the computing device 100 evaluates the reception time and quality of the response signal to confirm the stability and continuity of the communication. This evaluation may include the delay time of the signal, the data loss rate, the signal strength, etc.

For example, when the computing device 100 receives the response signal from the master logger within 10 minutes, the computing device 100 may recognize the response signal as a communication restoration signal. In this case, the computing device 100 may determine that the communication has been stably restored according to the quality of the response signal, for example, when the signal strength is-70 dBm or higher or the data packet loss rate is less than 1%.

When the computing device 100 recognizes that the communication of the master logger is restored, the computing device 100 may deactivate the alternative communication protocol (S320). In addition, the computing device 100 may recognize the states of charge of each of the plurality of data loggers 200 in connection with deactivating the alternative communication protocol (S330). The computing device 100 may determine the specific data logger 200 corresponding to the highest state of charge among the states of charge of each of the plurality of data loggers 200 as the master logger (S340).

Specifically, the computing device 100 may apply an algorithm that periodically monitors the battery state of all the data loggers connected to the network and preferentially re-selects the logger with the highest state of charge as the master logger. In addition, the computing device 100 may select the optimal master logger by considering various parameters such as the location of the logger, data transmission capability, and the network connection state in addition to the state of charge information. Through this process, the computing device 100 may maximize the energy efficiency of the entire network and ensure the reliability of data transmission.

For example, the computing device 100 may confirm the states of charge of each data logger connected to the network and preferentially select a logger with a state of charge of 80% or more. In addition, the computing device 100 selects the logger with the highest state of charge as the master logger when the logger with the highest state of charge is located at the center of the network and has a data transmission speed of 1 Mbps or more per second. In this way, the computing device 100 may achieve efficient management of the entire network and optimization of data transmission.

According to an additional embodiment of the present invention, the computing device 100 may determine the master logger based on a destination-based neural network model.

Specifically, the computing device 100 may train the neural network model based on data on the operation pattern, battery consumption rate, location change, etc., of the data logger 200 for each destination. The computing device 100 may input the destination into the trained neural network model and determine at least one of the data loggers 200 as the master logger.

For example, the computing device 100 may analyze the movement pattern, battery usage status, and location change record of the previous data logger 200 for a specific destination. The data may be processed through the neural network model to derive selection criteria for a master logger optimized for a specific destination. For example, the criteria may include characteristics of a logger that has less battery consumption on the route to the specific destination, an optimal location for fast data transmission, etc.

For example, the computing device 100 may identify, through the neural network model, the pattern that the specific data logger 200 operates more efficiently due to high building density and strong radio interference in the case of a storage device delivered to an urban area. Based on this, the computing device 100 may preferentially select the data logger with these characteristics as a master logger, for a storage device scheduled to be delivered to an urban area.

Therefore, by utilizing the destination-based neural network model, the computing device 100 may select the most suitable data logger as a master logger according to destinations of each delivery, thereby increasing the efficiency of the entire logistics process and optimizing the battery life.

According to an additional embodiment of the present invention, the computing device 100 may determine a master logger based on a neural network model based on an energy consumption rate.

Specifically, the computing device 100 may train the neural network model based on an identification code corresponding to each of the plurality of data loggers 200 and an energy consumption pattern corresponding to the identification code. In addition, the computing device 100 may recognize energy consumption patterns of several data loggers by inputting the identification codes of each of the data loggers that have started moving to the destination to the trained neural network model. In addition, the computing device 100 may determine the master logger based on the energy consumption patterns of several data loggers.

For example, the computing device 100 may collect the past and present energy consumption data of several data loggers 200. The data may reflect relationships with various factors, such as the location of the logger, the environmental conditions, and the movement patterns by being associated with the identification code of each logger. This information may be input to the neural network model and used to predict and understand the energy consumption patterns under specific conditions.

For example, the computing device 100 may identify a data logger with a pattern of low energy consumption under specific climate conditions or geographical environments. For example, a data logger with a longer battery life in a cold climate may be identified, and based on this information, the logger may be selected as a master logger when it is delivered to a cold area.

That is, the computing device 100 may designate the data logger most suitable for each delivery destination and condition as the master logger in order to optimize the energy consumption. This improves the energy efficiency of the entire logistics network, thereby maximizing the battery life of the data logger.

According to an additional embodiment of the present invention, the computing device 100 may record the data received from the master logger on the blockchain network, thereby ensuring the integrity of the data.

Specifically, the computing device 100 may issue a transaction that records all location data and environmental monitoring results of the data logger, transmit the issued transaction to at least one node composed of a plurality of terminals related to the goods stored in the storage device, and record the issued transaction in the blockchain network.

For example, the computing device 100 may convert location data and environmental data (e.g., temperature, humidity, vibration, etc.) collected from the data logger installed in each storage device where specific goods are stored into a transaction of the blockchain. This transaction may include information on the movement and storage state of products related to the corresponding storage device and may be distributed and recorded in various terminals connected to the blockchain network.

For example, the computing device 100 may record data on a path that a specific product has passed, the expected arrival time, and the environmental conditions, and then transmit the data to nodes belonging to terminals of each participant (e.g., a manufacturer, a logistics company, a retailer, an end consumer, etc.) in the logistics network. Each node may verify the received data and add the verified data to the blockchain, thereby sharing the reliable information through the entire supply chain without changing or manipulating the data.

In this way, the present invention may play an important role in confirming the origin of goods, verifying authenticity, assuring quality, etc., by providing data transparency and traceability. In addition, the immutability characteristic of the blockchain may prevent the record of the data loggers from being manipulated or changed and enhance the reliability of the entire logistics network.

Although exemplary embodiments of the present invention have been described with reference to the accompanying drawings, those skilled in the art will understand that various modifications and alterations may be made without departing from the spirit or essential feature of the present invention. Therefore, it is to be understood that the exemplary embodiments described hereinabove are illustrative rather than being restrictive in all aspects.

1. A method of tracking a location based on data loggers that optimize battery life, which is performed by a computing device including at least one processor, the method comprising:
recognizing a plurality of storage devices in which goods having the same destination are stored;
determining at least one of a plurality of data loggers provided in the plurality of storage devices to be a master logger;
receiving data related to the storage device provided with the master logger from the master logger; and
tracking locations of the plurality of storage devices based on the data.

2. The method of claim 1, wherein the determining of the at least one of the plurality of data loggers provided in the plurality of storage devices to be the master logger includes:
recognizing states of charge of each of the plurality of data loggers; and
determining a specific data logger corresponding to a highest state of charge among the states of charge of each of the plurality of data loggers to be the master logger.

3. The method of claim 1, further comprising:
after the master logger is determined, monitoring whether the master logger is in a communication failure state; and
when it is recognized that the master logger is in the communication failure state, activating an alternative communication protocol.

4. The method of claim 3, wherein the communication failure state includes a radio blocking state or a weak electric field state, and
the monitoring of whether the master logger is in the communication failure state includes:
monitoring whether the communication failure state is the radio blocking state based on whether data is received from the master logger at each preset cycle; or
monitoring whether the weak electric field state occurs based on whether a difference between a first time corresponding to the preset cycle and a second time at which the data is received from the master logger exceeds a preset time.

5. The method of claim 3, wherein the activating of the alternative communication protocol includes:
determining some of the plurality of data loggers to be the master logger;
receiving multiple pieces of data from each of the plurality of master loggers; and
tracking locations of the plurality of storage devices based on the multiple pieces of data.

6. The method of claim 5, wherein the tracking of the locations of the plurality of storage devices based on the multiple pieces of data includes:
recognizing a plurality of latitude values and a plurality of longitude values included in the multiple pieces of data;
recognizing a specific latitude value having a largest mutual overlap frequency among the plurality of latitude values and recognizing a specific longitude value having a largest mutual overlap frequency among the plurality of longitude values; and
tracking the locations of the plurality of storage devices based on the specific latitude value and the specific longitude value.

7. The method of claim 5, further comprising:
monitoring whether the communication of the master logger is restored after the activating of the alternative communication protocol;
deactivating the alternative communication protocol when it is recognized that the communication of the master logger is restored;
recognizing the states of charge of each of the plurality of data loggers in connection with the deactivating of the alternative communication protocol; and
re-determining a specific data logger corresponding to a highest state of charge among the states of charge of each of the plurality of data loggers to be the master logger.

8. The method of claim 7, wherein the monitoring of whether the communication of the master logger is restored includes:
transmitting a response request signal to the master logger in the communication failure state at each preset time; and
monitoring whether the communication of the master logger is restored based on a response signal corresponding to the response request signal,
wherein, when the response signal corresponding to the response request signal is not received from the master logger, it is recognized that the communication of the master logger in the communication failure state is not restored, and
when the response signal is received from the master logger and a time at which the response signal is received is included within a preset time from a time at which the response request signal is transmitted, it is recognized that the communication of the master logger in the communication failure state is restored.

9. An apparatus for performing the method of claim 1, comprising:
a memory configured to store one or more instructions; and
a processor configured to execute the one or more instructions stored in the memory,
wherein the processor performs the method of claim 1 by executing the one or more instructions.

10. A computer program coupled to a computer, which is hardware, and stored in a computer-readable recording medium to perform the method of claim 1.
